(19) United States
(12) Patent Application Publication
(10) Pub. No.: US 2009/0188562 A1
(43) Pub. Date: Jul. 30, 2009

(54) FIN-TYPE COMPOUND PARABOLIC CONCENTRATOR

(75) Inventor: Alexander J. Pavlak, Severna Park, MD (US)

Correspondence Address: LAUBSCHER & LAUBSCHER, P.C., 1160 SPA ROAD, SUITE 2B, ANNAPOLIS, MD, 21403, US

(73) Assignee: THALES RESEARCH, INC., Severna Park, MD (US)

(21) Appl. No.: 12/349,795

(22) Filed: Jan. 7, 2009

Related U.S. Application Data
(60) Provisional application No. 61/024,277, filed on Jan. 29, 2008.

(51) Int. Cl. H01L 31/00

(52) U.S. Cl. 136/259

(57) ABSTRACT

A fin-type compound parabolic concentrator includes a pair of semi-parabolic reflectors arranged on opposite sides of a common plane, the reflectors having a common focal point on the plane and being rotated through an angle defined by a line extending from the apex of each reflector through the focal point. A generally arcuate bottom reflector having a center line within the common plane is connected with the semi-parabolic reflectors. A bi-facial photovoltaic absorber is arranged in the common plane and extends from the focal point to the bottom reflector for absorbing rays of sunlight directed thereon from the reflectors. The absorber has a critical angle below which rays directed thereon will be substantially absorbed and above which rays directed thereon will be substantially reflected and the bottom reflector is configured to limit the angle of rays that strike said absorber to less than said critical angle.

This application claims the benefit of U.S. provisional application No. 61/024,277 filed Jan. 29, 2008.

### BACKGROUND OF THE INVENTION

The present invention relates to fin type compound parabolic concentrators (FT-CPCs) for use as static concentrators in cost effective solar photovoltaic (PV) systems. More specifically, the invention includes geometries that limit the angle of reflected rays striking the PV cell. This is called a θᵢ θₒ FT-CPC or a θₒ FT-CPC where θᵢ is the angle of rotation of the semi-parabolic reflectors of the concentrator and θₒ is the critical angle of the PV cell.

### BRIEF DESCRIPTION OF THE PRIOR ART

A system based on FT-CPCs is disclosed in the L'Esperance U.S. Pat. No. 4,024,852 and a number of reflector shapes for such concentrators are disclosed in the Winston U.S. Pat. No. 4,002,499. These reflector shapes including a FT-CPC have since come to be known as ideal concentrators.

There are two main types of compound parabolic concentrators using flat absorbers. The first is a fin type (FT-CPC) as shown in FIG. 1 and the second is a plate type (PT-CPC) as shown in FIG. 2. In FIGS. 1 and 2, both types are drawn to the same scale with the same input aperture aᵢ, output aperture aₒ, and field-of-view, 2θᵢ=60°.

The FT-CPC shown in FIG. 1 has semi-parabolic reflector walls 8 having a common focal point 4 and a fin-like absorber 2 positioned between the focal point and the apex 18. For photovoltaic (PV) applications, the absorber is a bi-facial solar cell.

The PT-CPC shown in FIG. 2 has a plate-like monofacial absorber 2 positioned horizontally. The walls are semi-parabolic with the right side 8 having a focal point at 12. The left side 6 has its focal point at 10. For PV applications, the absorber is a monofacial photovoltaic cell.

A major advantage of the FT-CPC over the PT-CPC is that in the former, the exit aperture is on both sides of the fin. As a result, FIG. 1 shows that the height of the bi-facial fin is half the width of the monofacial plate with the same optical properties. This means that photovoltaic wafer costs and any single step processing costs are approximately half of those for the plate type compound parabolic concentrators.

Ideal concentrators are a subset of non-imaging concentrators. Non-imaging concentrators are better suited than imaging concentrators for solar collectors because they can be designed to have a flat response over a range of angles. Ideal concentrators have a response that is either 100% or 0%. They are “ideal” in that they achieve a theoretical limit, specifically, the highest concentration ratio for a given field-of-view. This theoretical foundation is important because if expensive solar cells are to be replaced with relatively inexpensive reflectors, then the fin-type compound parabolic concentrator with its bifacial fin is the ultimate static concentrator.

All conventional reflector-absorber configurations fall short of this theoretical limit, sometimes significantly. This limit can also be derived from the second law of thermodynamics. For a two dimensional trough, the theoretical limit is:

CR1ₘₓ=1/sin θᵢ (1)

where 2 θᵢ is the field-of-view.

An intuitive method of constructing a fin-type compound parabolic concentrator is presented in FIG. 3. Start with a basic parabola, the dashed line 22. The parabola has a focal point 4 and a symmetry axis 20. From the definition of a parabola, all of the light arriving parallel to the symmetry axis 20 will be reflected off the parabola to strike the focal point 4.

The fin-type compound parabolic concentrator can be constructed by independently rotating the right side and the left side of the parabola about the focal point. In FIG. 3, the right side is rotated counter counterclockwise by the angle θᵢ resulting in a new semi-parabolic shape 8 having an axis 24. Likewise, the left side is rotated clockwise by the angle θᵢ resulting in a new semi-parabolic shape 6 with axis 26. The new compound parabolic shape has a gap between the two-semi parabolic apexes 14 and 16.

As described in the Winston U.S. Pat. No. 4,002,499, the gap between the semi-parabolic apexes can be completed with an involute of the absorber. The involute of a flat or fin absorber is a circular arc centered on the focal point. Completing the gap with a circular arc results in exit angles, the angle at which light rays are incident on the absorber, to be unconstrained. Reflected light strikes the absorber at all angles between ±90°. This is characteristic of the classic ideal fin-type compound parabolic concentrator.

FIGS. 4 and 5 show ray traces of a classic fin-type compound parabolic reflector. All of the light arriving over the range of angles ±θᵢ will strike the fin. FIG. 4 shows light arriving at the extreme angle −θᵢ parallel to the axis 24 of the right semi-parabolic wall 8. Since the light is parallel to the semi-parabolic axis, all of the light striking the right half of the compound parabolic concentrator is reflected back to the focal point 4. That light striking the left half 6 of the fin-type compound parabolic reflector is also reflected to strike the fin 2.

From FIG. 4 it will be seen that if light arrives at an angle beyond the range ±θᵢ, light striking the far side semi-parabola would pass above the focal point and the amount of light striking the fin 2 would drop dramatically.

The ray trace illustrated in FIG. 5 shows what happens when light arrives parallel to the common plane 20. All of the light is reflected to pass between the apex 18 and the focal point 4 striking the fin absorber 2.

With the classic ideal concentrators shown in FIGS. 1 and 2, all of the light arriving between the design angles ±θᵢ will strike the absorber. All of the light arriving outside of this range of angles is rejected. The angle of light rays striking the absorber is unconstrained. That is, if arriving light is uniformly distributed over the angles ±θᵢ, the light striking the absorber would be uniformly distributed over the angles ±90°.

A θₒ concentrator limits the angle of light striking the absorber to ±θₒ about the perpendicular to the absorber surface. Limiting the angle is important because light striking real absorbers at high incidence angles or grazing angles cannot be absorbed.

Silicon solar cells have an index of refraction in the neighborhood of n₂=3.5. As a result, some of the light striking the solar cell after passing through air n₁=1.0, or glass n₁=1.5 will be reflected back off the photovoltaic surface. This reflection is particularly acute for light rays striking the solar cell at high angles of incidence. There is a critical angle θₒ beyond which most of the light will be reflected off the surface.

The incidence angle reflection is illustrated in FIG. 6. A solar cell 36 has a perpendicular 30. For a given index of refraction there is a critical angle θₒ beyond which incident energy is substantially reflected off of the surface of the cell. In FIG. 6, light ray 34 would be substantially reflected off the surface whereas light ray 32 would be substantially transmitted or absorbed. The present invention was developed to provide a fin-type compound parabolic concentrator where substantially all of the rays striking the solar cell arrive within the design range of angles ±θₒ.

Referring to FIG. 6, with non-polarized light, if n₁=1 (air) and n₂˜1.5 (glass, acrylic) then θₒ˜60°. Solar cells can have an index of refraction as high as 4.5 and may include a glazing material, and the incident light can be highly polarized. Anti-reflective coatings on the solar cell surface are often used to minimize reflection at certain angles and wavelengths. So, θₒ depends on a number of design and operating conditions. In all cases, however, grazing rays tend to be reflected, and limiting θₒ is an essential design feature. In practical photovoltaic concentrators, there will be a balance between θₒ and the anti-reflective coatings.

The concept of limiting both the input and output angles as a θᵢ θₒ ideal concentrator is apparent from the prior art. That is, both the input aperture ±θᵢ and the output aperture ±θₒ are defined and limited. The θᵢ θₒ concept was first disclosed in the Rabl U.S. Pat. No. 4,130,107. A notable generalization from this prior art is that the theoretical maximum concentration ratio is now:

CR2ₘₓ=sin θₒ/sin θᵢ (2)

If all exit angles were allowable, θₒ=90° and equation 2 becomes equation 1.

Prior art relating to θᵢ θₒ focused on innovations for limiting exit angles for a plate type compound parabolic concentrator and a tube type ideal concentrator. The specific innovations are quite different for different types of ideal concentrators. Such prior art does not refer to or provide guidance for a fin-type compound parabolic concentrator. In addition to not providing guidance about how to construct a θᵢ θₒ fin-type compound parabolic concentrator, the prior art does not provide any assurance that an ideal θₒ fin-type compound parabolic concentrator exists.

### SUMMARY OF THE INVENTION

Accordingly, it is an object of the present invention to create the geometry that limits the angle of light striking a bi-facial photovoltaic cell when a flat bi-facial photovoltaic cell is employed as the fin in a fin-type compound parabolic concentrator.

According to a primary object of the invention, fin-type compound parabolic concentrator has geometries that limit the angle of reflected rays incident on the fin. The angle is limited to less than or equal to a critical angle θ_{o.} To achieve this it is necessary to truncate the reflector and alter the geometry in the vicinity of the apex. These geometries are consistent with theoretical limits and are a close approximation to an ideal θᵢ θₒ fin-type compound parabolic concentrator. The invention includes three main components. First, the top of the reflector is truncated. It is common practice to arbitrarily truncate fin-type compound parabolic concentrators for mechanical convenience in order to avoid designs that are awkward to build because they are very deep. A novel aspect of this invention is to provide limits, so that truncating to the limit results in little optical loss because rays reflected off the outer limb of the reflector strike the absorber at angles>θₒ. Truncating beyond the limit involves optical loss because reflected rays strike the absorber at angles<θₒ.

Second, the apex geometries are modified to limit the angle of reflected rays. A fin-type compound parabolic concentrator apex geometry is determined by the reflection behavior of limiting rays. Limiting rays are incoming rays at different angles θ<θᵢ that pass just above the focal point. A limiting apex geometry limits the reflected limiting ray to strike the absorber at an angle less than or equal to some critical angle θₒ. An optimum geometry, the θₒ apex geometry, is a specific equation that maximizes concentration ratio consistent with the constraint of limiting rays striking the absorber to angles≦θₒ. Another geometry, referred to as βₜ apex geometry uses a simple straight line tangent. This is a crude but useful approximation that limits reflected rays to less than θₒ but reduces the concentration ratio to less than the optimum. The invention also relates to a range of ad hoc apex geometries between the optimum and the crude approximation.

Third, connection geometries are provided between the limiting apex geometry and the semi-parabolic reflectors. The combination of the limiting apex geometry and the connection geometry are incorporated into a bottom reflector. The invention includes three different connection structures depending on the relationship between the design parameters θᵢ and θₒ. For example, if

θᵢ=90°−θₒ

the limiting apex geometries are tangent to and connect with the semi-parabolic wall at the semi-parabolic apex. If

θᵢ<90°−θₒ

the connection geometry is a straight line that is tangent to both the semi parabolic wall as some F distance from the apex and to the limiting apex geometries. If

θᵢ>90°−θₒ

the connection geometry is a circular arc that is tangent to both the limiting apex geometries and the semi parabolic apex.

It is not possible to build an “ideal” θᵢ θₒ fin-type compound parabolic concentrator. A small number rays will directly strike the absorber without reflection at angles greater than θₒ. For this reason a θᵢ θₒ fin-type compound parabolic concentrator is not theoretically an “ideal” concentrator, but it is a close approximation.

### BRIEF DESCRIPTION OF THE DRAWINGS

FIG. 1 is a schematic diagram of a bi-facial fin-type compound parabolic concentrator according to the prior art;

FIG. 2 is a schematic diagram of a mono-facial plate-type compound parabolic concentrator according to the prior art;

FIG. 3 is a schematic diagram illustrating a method of constructing a fin-type compound parabolic concentrator according to the prior art;

FIG. 4 is a ray trace diagram for rays arriving at the maximum design angle θᵢ of a fin-type compound parabolic concentrator according to the prior art;

FIG. 5 is a ray trace diagram for rays arriving on axis of a fin-type compound parabolic concentrator according to the prior art;

FIG. 6 is a schematic diagram showing the reflection of grazing rays off a dielectric material having a critical angle θₒ according to the prior art;

FIG. 7 is a schematic diagram of a fin-type compound parabolic concentrator according to the invention;

FIG. 8 is a detailed schematic diagram of the apex portion of a fin-type compound parabolic concentrator according to the invention;

FIG. 9 is a vector diagram of the polar coordinates for calculating the θₒ apex geometry of a fin-type compound parabolic concentrator according to the invention;

FIG. 10 is a vector diagram of the reflection angles used to calculate the θₒ apex geometry of a fin-type compound parabolic concentrator according to the invention;

FIG. 11 is a graphical representation of the shape of the θₒ apex geometry of FIG. 9;

FIG. 12 is a detailed schematic diagram of the apex portion of a fin-type compound parabolic concentrator according to the invention the design having parameters θᵢ=90°−θₒ;

FIG. 13 is a detailed schematic diagram of the apex portion of a fin-type compound parabolic concentrator according to the invention having parameters θᵢ<90°−θₒ; and

FIG. 14 is a detailed schematic diagram of the apex portion of a fin-type compound parabolic concentrator according to the invention parameters θᵢ>90°−θₒ.

### DETAILED DESCRIPTION

The invention relates to a fin-type compound parabolic concentrator which is designed to limit the light striking the photovoltaic cell absorber to an angle less than or equal to a critical angle θₒ. There are three components to the invention: truncating the semi-parabolic reflectors of the concentrator; configuring the limiting apex geometry of the bottom reflector of the concentrator; and connecting the apex geometry with the semi-parabolic reflectors.

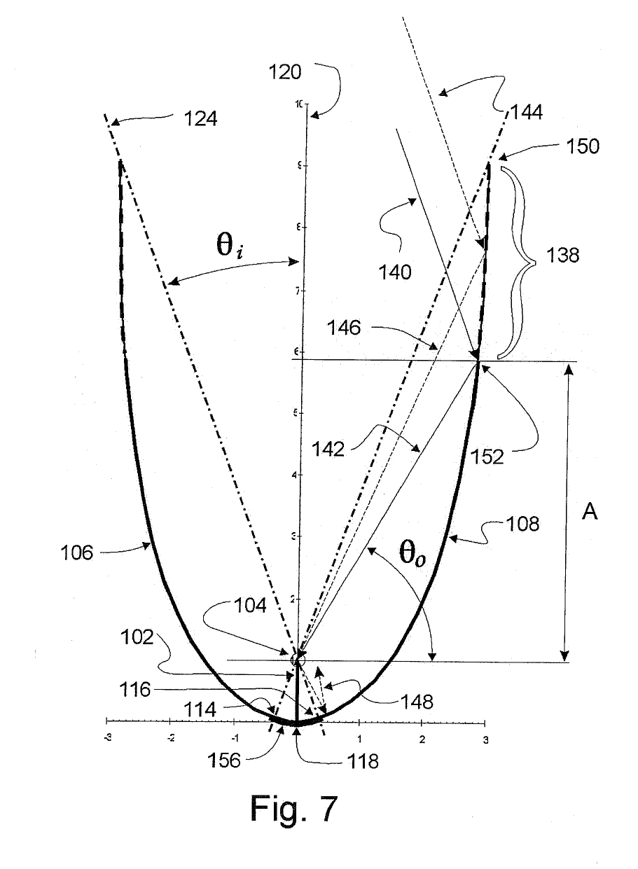

Referring to FIG. 7, there is shown a fin-type compound parabolic concentrator 150 including a pair of opposed semi-parabolic reflectors 106, 108 arranged on opposite sides of a common plane 120 and having a focal point 104 on the common plane. The reflectors are rotated in opposite directions relative to the common plane through a rotational angle θᵢ defined by lines extending from the apexes 114, 116 of each semi-parabolic reflector through the focal point 104. The concentrator further includes a generally arcuate bottom reflector 156 having an apex 118. The concentrator thus is shaped like a trough. A bi-facial photovoltaic cell or absorber 102 absorbs solar energy from rays of sunlight reflected thereon by the semi-parabolic reflectors 106, 108 and by the bottom reflector 154. The absorber is coplanar with the common plane 120 and extends from the focal point 104 to the apex 118 of the bottom reflector 156. The absorber has a critical angle θₒ.

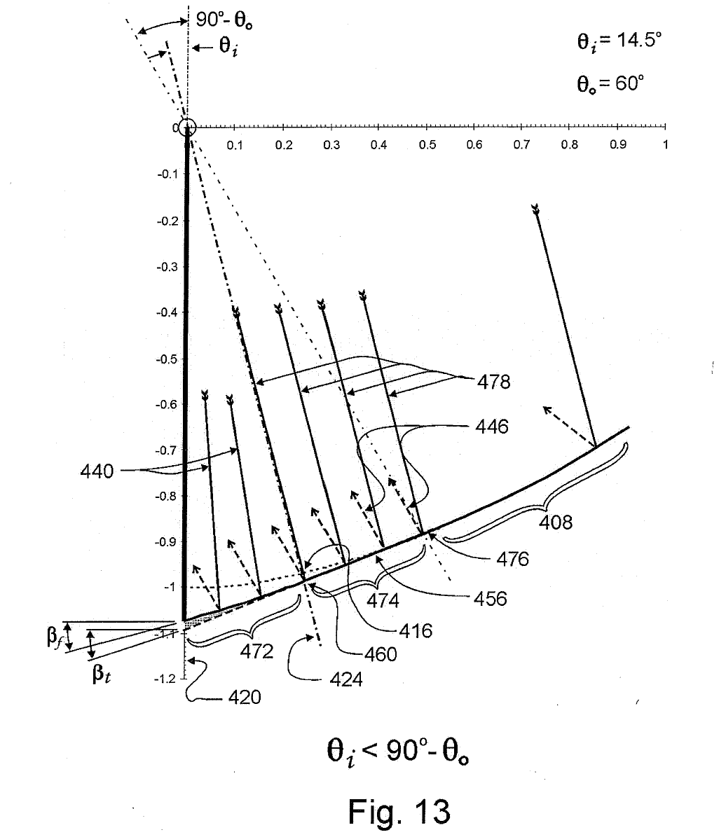

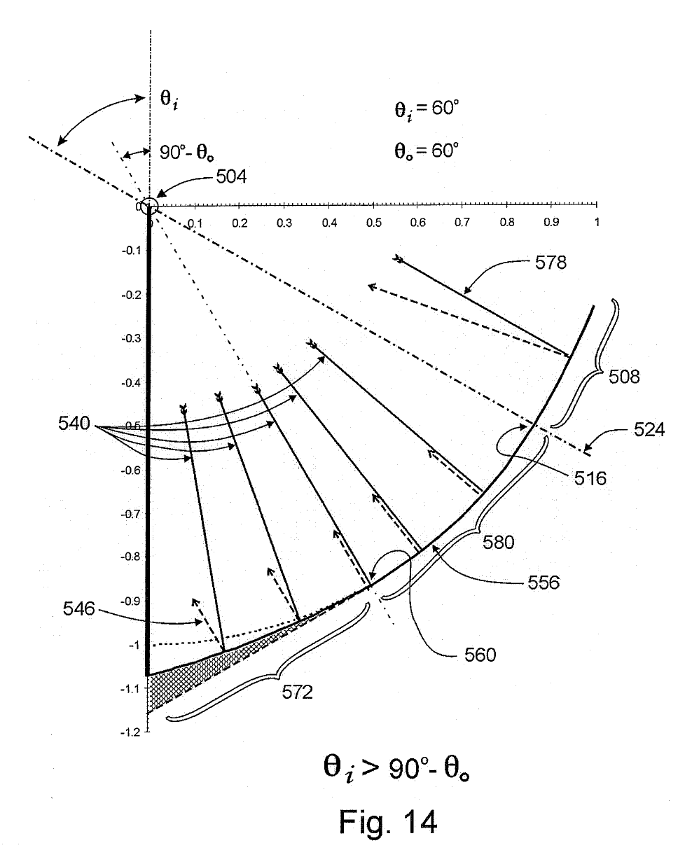

The bottom reflector has a configuration adjacent to the apex which limits reflected light to angles≦θₒ. As will be developed in greater detail below in connection with FIGS. 13 and 14, the bottom reflector may include an additional connection portion for connection with the semi-parabolic reflectors.

In FIG. 7, ray 144 is an extreme ray in that it arrives parallel to the right side parabola axis 124 at the extreme angle θᵢ. Ray 144 is reflected as ray 146 striking the absorber 102 at an angle greater than the absorber critical angle θₒ. Since the strike angle is greater than θₒ, ray 146 is not absorbed but is reflected off the absorber and back into space as illustrated by 148.

In FIG. 7 point 152 is the useful limit of the reflector. It is defined by ray 140, arriving at the extreme angle θᵢ, reflecting as ray 142 which strikes the absorber at the focal point 104 and at the critical angle θₒ.

The outer portion 138 of the semi-parabolic reflector 108 is not very useful because light reflected off this portion strikes the absorber at high incidence angles. This light is not absorbed by the absorber but rather is reflected back into space. Thus, the outer portion 138 can be removed with little reduction in optical efficiency of the concentrator. The limiting point is at 152, the point where the extreme ray 144 is reflected to strike the absorber at the critical angle θₒ. The distance A is the height of the truncated reflector above the focal point 104. From basic geometry, the distance A can be shown to be:

A=2 sin θₒ/[1−sin(θₒ−θᵢ)] (3)

where
A is measured in focal length units
θₒ=output angle aperture, absorber critical angle
θᵢ=input angle aperture, semi-parabola rotation, half the field-of-view of the concentrator

The most efficient fin-type compound parabolic concentrator would have a height above the focal point given by equation (3). Practical fin-type compound parabolic concentrators have tolerances, rounded corners, and dead space to avoid exposed reflector metal edges. With tolerances, the working portion of the reflector should be as high or higher than equation (3) but not shorter. Shorter geometries introduce significant optical losses. Taller geometries add cost but collect little or no additional light.

Truncation has value for fin-type compound parabolic concentrator configurations with high concentrations and wide fields of view in accordance with the following relation between parabolic rotational angles and absorber critical angles:
α θᵢ<90°−θₒ truncation is useful
α θᵢ≧90°−θₒ truncation is not necessary since all rays arrive within the field of view ±θᵢ are reflected to strike the absorber at angles less than the critical angle ±θₒ.

Truncating the top of the reflectors results in little optical loss because rays reflected off the outer portions of the reflectors would strike the absorber at angles>θₒ and hence the ray would be reflected off the photovoltaic cell and not absorbed.

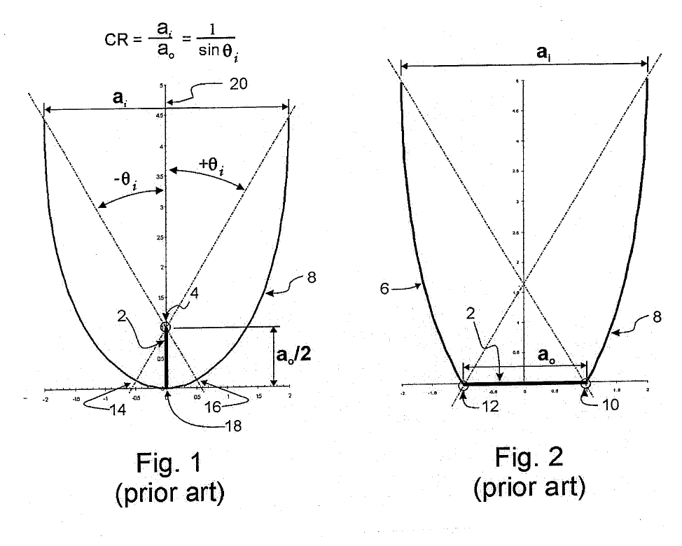

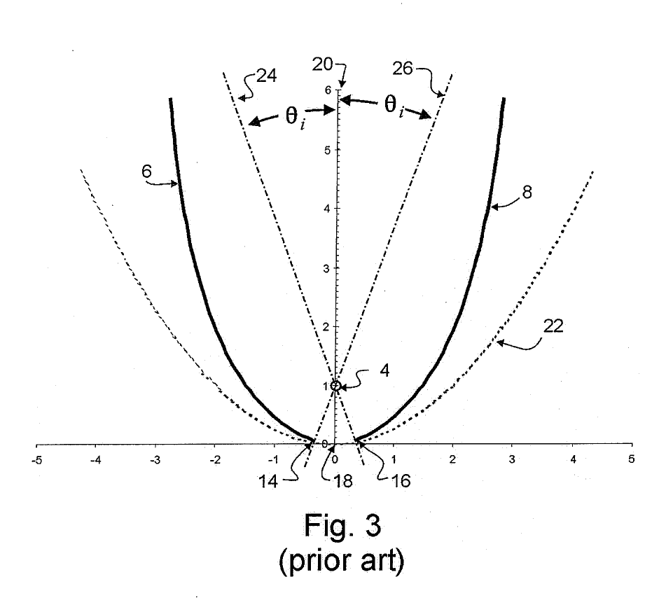

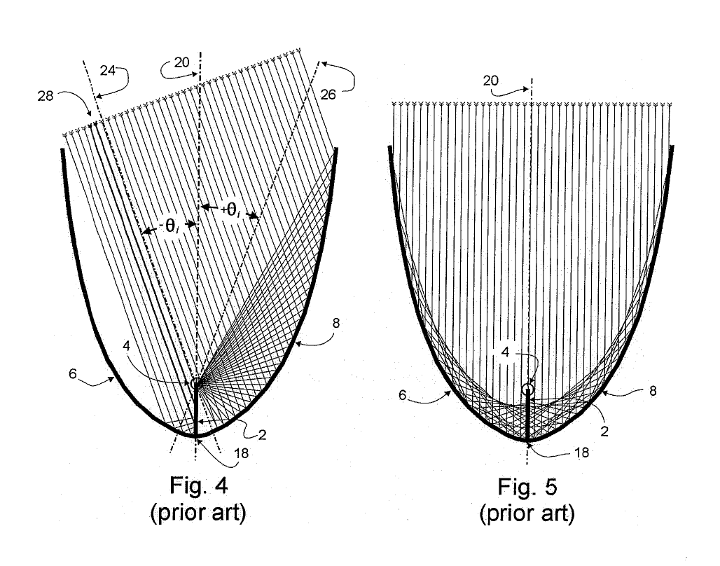

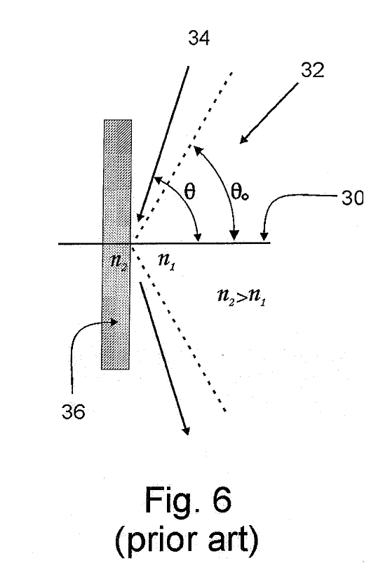

Turning now to the configuration of the bottom reflector, the geometry thereof preferably limits the angle of reflected rays near the apex. With a conventional fin-type compound parabolic concentrator as shown in FIG. 1, the bottom reflector is a circular arc connecting the semi-parabolic apexes 14 and 16 to the common plane 20 at the apex 18. A limiting apex geometry in accordance with the invention is a profile that also limits the angle of reflected rays to ≦θₒ.

Three limiting apex geometries of the bottom reflector for limiting the angle that rays strike the absorber to less than a critical angle θₒ are disclosed. The preferred embodiment is referred to as the θₒ apex geometry. A second embodiment is referred to as βₜ apex geometry, and a third embodiment includes a range of geometries.

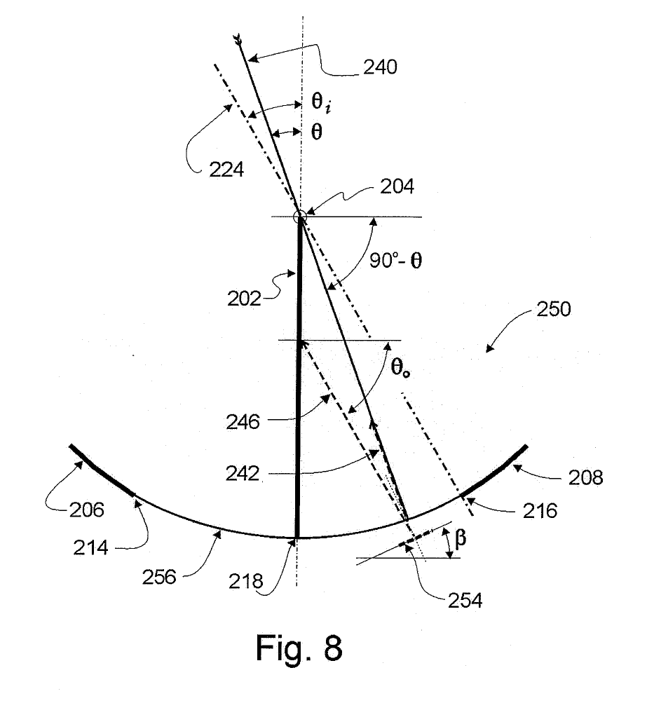

As noted earlier, the conventional fin-type compound parabolic concentrator has no constraints on the angle of incidence of light striking the fin absorber. That is, the rays striking the fin have incidence angles ranging from ±90° and equation (1) applies. The difficulty with unconstrained incidence angles is illustrated in FIG. 8 where the fin-type compound parabolic concentrator 250 is expanded in the vicinity of its apex 218. A bottom reflector 256 configured as a circular arc is centered on the focal point 204 is connected with the semi-parabolic reflectors 206 and 208 at the apexes 214 and 216 thereof, respectively. The semi-parabolic reflector 208 has an axis 224. Consider a limiting ray 240, i.e. a ray passing just above the focal point. Ray 240 arrives at an angle θ within the field of view θᵢ. Ray 240 would be reflected off the circular arc of the bottom reflector 256 of the concentrator to become ray 242 striking the absorber 202 just below the focal point 204.

For circular arcs and practical absorbers, limiting rays are not absorbed whenever (90°−θ)>θₒ. This occurs next to the absorber where θ˜0. The challenge is to find a new shape 254 for the bottom reflector 256 with a local slope β such that limiting rays are reflected to strike the absorber at the critical angle θₒ as illustrated by reflected ray 246.

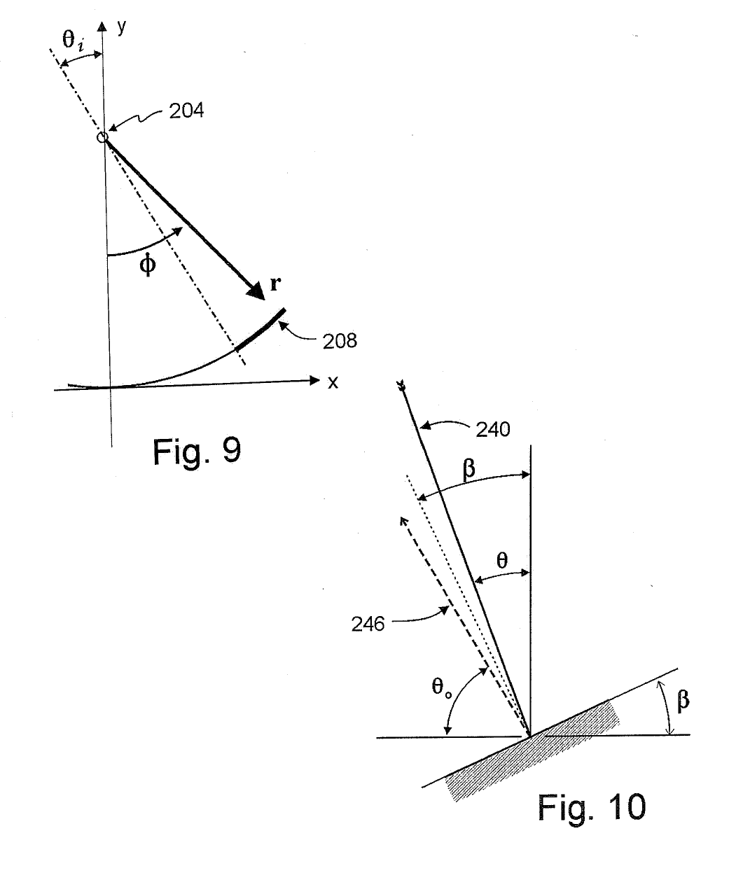

FIGS. 9 and 10 illustrate the coordinate system and variables for deriving the θₒ apex geometry. The polar coordinates are r, φ. The coordinate r, normalized to unit focal length, is measured from the focal point 204. The angular coordinate φ is measured counterclockwise from the absorber. Using the reflection angles shown in FIG. 10, the reflector slope β required to reflect the limiting incoming ray 240 at angle θ to ray 246 at angle θₒ is:

β(θ)=45°+(θ−θₒ)/2 (4)

At the intersection of the θₒ apex geometry of the bottom reflector 256 with the absorber 202 (FIG. 8), the angle of the limiting ray must be θ˜0 and the slope of the θₒ apex geometry of the bottom reflector at the absorber β_{f} is:

β_{f}=45°−θₒ/2 (5)

The geometry extends away from the absorber out to a tangent point where the reflected ray 246 is returned to the focal point. There are two solutions for βₜ, the slope of the θₒ apex geometry of the bottom reflector at the tangent, depending on the relationship between θᵢ and θo:

βₜ=45°+(θᵢ−θₒ)/2 when θᵢ<90°−θₒ (6)

βₜ=90°−θₒ when θᵢ≧90°−θₒ (7)

Integrating the slope as in equation (4) results in the following equation for the θₒ apex geometry of the bottom reflector:

r(φ)/rₒ=cos⁻² α (8)

where
α=45°−(θₒ+φ)/2
When θᵢ≧90°−θₒ, rₒ=1.0, the focal length.
When θᵢ<90°−θₒ, rₒ is calculated to merge the θₒ apex geometry into the reflector at βₜ.

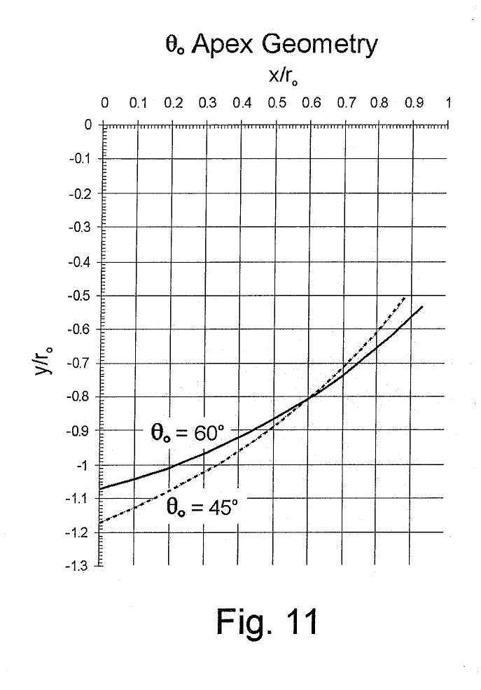

FIG. 11 is a graph of the θₒ apex geometry for θₒ=45° and 60°. From equation (8), the θₒ apex geometry for the bottom reflector includes of a family of curves, each specific to a critical angle θₒ. The θₒ apex geometry is a preferred embodiment because it limits absorber strike angles to ≦θₒ while simultaneously maximizing the concentration ratio.

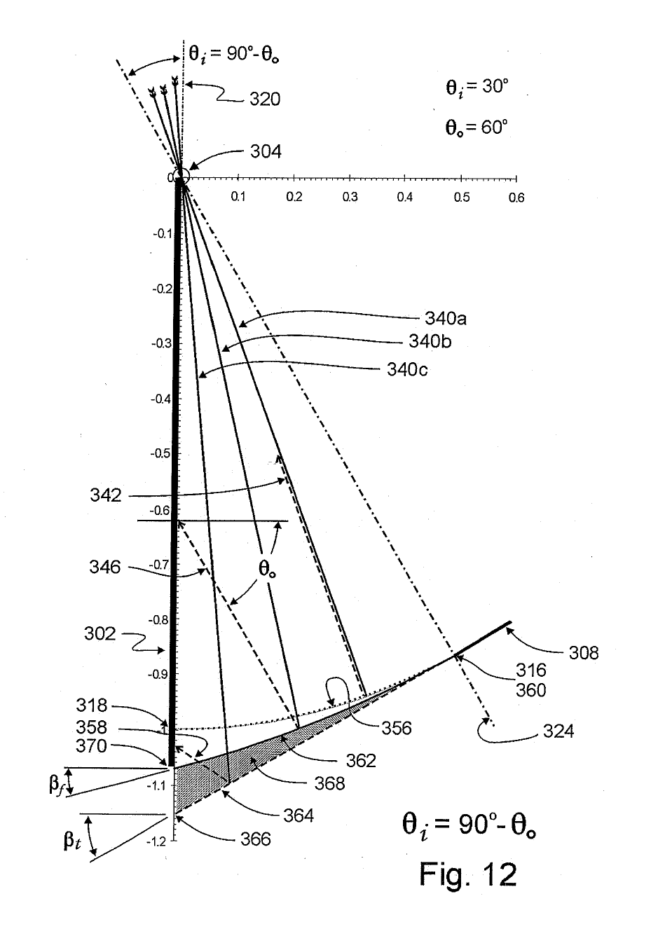

FIG. 12 shows several apex geometries including the well-known circular arc 356 and the three novel limiting apex geometries, i.e. the θₒ apex geometry 362, the βₜ apex geometry 364, and a range of ad hoc geometries designated by the cross hatched area 368.

The circular arc of the bottom reflector 356 intercepts the absorber 302 perpendicular to the absorber at point 318 which is along the centerline of the bottom reflector. The θₒ apex geometry intercepts the absorber at angle β_{f} according to equation (5) at point 370. The βₜ apex geometry intercepts the absorber at angle βₜ according to equation (7) at point 366. The βₜ apex geometry is a simple straight line with slope βₜ intercepting the semi-parabolic reflector 308 at a tangent point 360 coincident (for the condition θᵢ=90°−θₒ) with the semi-parabolic apex 316 of the reflector. The axis 324 of the reflector passes through the apex.

The ad hoc geometries are shown by the hatched area of FIG. 12 and include profiles with a uniformly increasing slope that lie between the θₒ apex geometry and the βₜ apex geometry. More specifically, referring to FIG. 12, the ad hoc geometry intercepts the common plane 320 between the intercept of the θₒ apex geometry 370 and the intercept of the βₜ apex geometry 366, intercepts the common plane at an angle≦β_{f} as specified in equation (5), intercepts the next segment of the bottom reflector profile at the tangent point 360 at an angle=βₜ given by equations (6) or (7), whichever is appropriate, and has a continuously increasing slope between the common plane and point 360.

FIG. 12 further illustrates reflection angles associated with various bottom reflector geometries. A limiting ray 340a is reflected off the circular arc bottom reflector 356 to ray 342 striking the absorber at the focal point 304 at an angle>θₒ. Another limiting ray 340b is reflected off the θₒ apex geometry of the bottom reflector to ray 346 striking the absorber at an angle=θₒ. Another limiting ray 340c is reflected off the βₜ apex geometry of the bottom reflector to ray 358 striking the absorber at an angle<θₒ.

As the angle of arrival θ of the limiting ray increases to approach the design maximum angle θᵢ, the angle at which all reflected rays 342, 346, 358 strike the absorber approaches θₒ.

The profile of the different geometries of the bottom reflector is determined by limiting rays that pass just above the focal point. As shown in FIG. 12, any non-limiting rays (i.e., θ<θᵢ for rays not grazing the focal point) striking a limiting apex geometry, will strike the absorber at angles less than limiting rays. Thus, any ray arriving within the field of view ±θᵢ and reflected off the θₒ apex geometry, the βₜ apex geometry, or the range of ad hoc geometries would strike the absorber at an angle≦θₒ.

Limiting the angle at which reflected rays strike the absorber decreases in the concentration ratio. In FIG. 1 the concentration ratio is defined as aₒ/aᵢ. For all four apex geometries 356, 362, 364, 368 of the bottom reflector shown in FIG. 12, the input aperture aᵢ is the same. For each of the three geometries, the absorber height aₒ/2 is different. For the circular arc 356 the absorber height is the distance between the focal point 304 and 318 (the focal length). For the θₒ apex geometry 362, the absorber length increases to the location designated by 370, decreasing the concentration ratio. For the β_{c} apex geometry 364, the absorber length increases further to 366 decreasing the concentration ratio even further. For the ad hoc geometries, the absorber length falls within the range defined between the locations 370 and 366.

In another embodiment of the invention, the bottom reflector is configured in such a way as to include an additional portion to connect the limiting apex geometry with the semi-parabolic reflector walls. The bottom reflector includes both the limiting apex geometry and the connection geometry. How this is accomplished depends on the relationship between the design parameters θᵢ and θₒ.

Referring to FIG. 8, the new apex geometry of the bottom reflector 254 does not necessarily connect with the semi-parabolic apexes 214 and 216. The apex geometry may require a connector portion extending beyond the semi-parabolic apexes 214 and 216 to connect with the semi-parabolic walls 206 and 208 at a tangent point replacing the lower portion of the semi-parabolic wall. Likewise, the new limiting apex geometry may not reach the semi-parabolic apexes and may require a connector portion of the bottom reflector to fill in the gap.

For the unique case where θᵢ=90°−θₒ, the apex geometry of the bottom reflector is connected with the semi-parabolic reflectors at the semi-parabolic apexes, one of which is shown at 316 for the semi-parabolic reflector 308 in FIG. 12. As shown therein, the semi-parabolic apex 316 and the tangent point 360 are coincident.

Referring now to FIG. 13, a bottom reflector 456 for the condition θᵢ<90°−θₒ is shown. Here, the bottom reflector includes a limiting apex geometry portion 472 as described above and a linear connector portion 474 which connects with the semi-parabolic wall 408. As described above, the limiting apex geometry of the bottom reflector includes either the θₒ apex geometry, the βₜ apex geometry, or a range of ad hoc geometries designated by the cross-hatched area of FIG. 12. The limiting apex geometry extends from the common plane 420 out to the axis 424 of the semi-parabolic wall 408. The profile of the limiting apex geometry is determined by the reflection behavior of limiting rays 440.

The profile of the connector reflector portion 474 between the axis 424 of the semi-parabolic wall 408 at the tangent point 460 and the tangent 476 to the semi-parabolic wall 408 is determined by extreme angle rays 478. Arriving at the extreme angle θᵢ, these rays are all reflected (see rays 446) to the angle θₒ by a straight line at the tangent angle

βₜ=45°+(θᵢ−θₒ)/2 equation (6)

With a conventional fin-type compound parabolic concentrator, the semi-parabolic wall would have its apex at 416 and transition into a circular arc to reflect limiting rays back to the focal point. With the θₒ concentrator of the invention, the semi-parabolic wall extends only to the tangent point 476 where it transitions into the straight connector reflector portion 474.

It should be noted that for the particular values of θᵢ and θₒ used in FIG. 13, the βₜ apex geometry is a good approximation to the θₒ apex geometry.

A θₒ fin-type compound parabolic concentrator for the condition θᵢ≧90°−θₒ is shown in FIG. 14. As before, the profile of the bottom reflector 556 near the absorber (the limiting apex geometry) is governed by limiting rays 540. For the condition θᵢ>90°−θₒ, the bottom reflector 556 includes two portions, the limiting apex geometries 572 and a concave connector portion 580. Preferably, the concave connector portion is a circular arc of constant radius. The purpose of the limiting apex geometry is to reflect a limiting ray 540 to ray 546 at θₒ. The limiting apex geometry extends to the tangent point 560 where the limiting ray is reflected back to the focal point 504. Between the tangent point 560 and the semi-parabolic apex 516, the connector portion 580 reflects limiting rays back to the focal point 504. Beyond the semi-parabolic apex 516, the semi-parabolic wall reflects extreme rays 578 back to the focal point.

It should be noted that for the particular values of θᵢ and θₒ shown in FIG. 14, the βₜ apex geometry significantly decreases the concentration ratio beyond that achievable with the θₒ apex geometry.

FIG. 4 shows two rays 28 that directly strike the fin-type bi-facial absorber 2 at an incidence angle greater than θₒ. For certain refractive index combinations, those rays will be reflected off the absorber and back into space. The number of rays lost in this manner is small and depends on the incidence angle θ and the design angle θₒ. At θ=0, no rays are lost. At θ=20° two rays out of 41 are lost. Since the rays are direct strikes, there are no reflector design solutions. This loss, while minor, precludes a theoretically ideal θᵢ θₒ fin-type compound parabolic concentrator.

While the preferred forms and embodiments of the invention have been illustrated and described, it will be apparent to those of ordinary skill in the art that various changes and modifications may be made without deviating from the inventive concepts set forth above.

What is claimed is:

1. A solar concentrator, comprising
(a) a pair of semi-parabolic reflectors arranged on opposite sides of a common plane, said reflectors each having an axis, an apex and a common focal point on said common plane, said reflectors being rotated in opposite directions relative to said common plane through a rotational angle defined by said semi-parabolic reflector axes, respectively;
(b) a generally arcuate bottom reflector having a center line within said common plane of said pair of semi-parabolic reflectors, said bottom reflector being connected with said semi-parabolic reflectors; and
(c) a bi-facial photovoltaic absorber arranged within said common plane of said semi-parabolic reflectors and extending from said focal point to said bottom reflector for absorbing rays of sunlight directed thereon from said reflectors, said absorber having a critical angle below which rays directed thereon will be absorbed and above which rays directed thereon will be reflected, said bottom reflector being configured to limit the angle of rays that strike said absorber to less than said critical angle.

2. A solar concentrator as defined in claim 1, wherein θᵢ=90°−θₒ, where
θᵢ is the rotational angle of said semi-parabolic reflectors
θₒ is the critical angle of said absorber
and further wherein said bottom reflector has an arcuate configuration and extends from the common plane to each semi-parabolic apex.

3. A solar concentrator as defined in claim 2, wherein said bottom reflector configuration on each side of said common plane is defined by the equation
r(φ)=cos⁻² α
where:
α=45°−(θₒ+φ)/2
r is measured in focal length units from said focal point
φ is an angle measured counterclockwise from said absorber.

4. A solar concentrator as defined in claim 2, wherein said bottom reflector has a slope β_{f} at the common plane greater than
β_{f}=45°−θₒ/2
said slope monotonically increasing from said bottom common plane to a slope βₜ of
βₜ=45°+(θᵢ−θₒ)/2
at the intersection with said semi-parabolic apex.

5. A solar concentrator as defined in claim 1, wherein θᵢ<90°−θₒ, where
θᵢ is the rotational angle of said semi-parabolic reflectors
θₒ is the critical angle of said absorber
and further wherein said bottom reflector comprises a first portion extending from said common plane, said first portion having an arcuate configuration and a second portion extending from said first portion to each semi-parabolic apex, said second portion having a linear configuration.

6. A solar concentrator as defined in claim 5, wherein the configuration of said bottom reflector first portion is defined by the equation
r(φ)/rₒ=cos⁻² α
where:
α=45°−(θₒ+φ))/2
r is measured in focal length units from said focal point
φ is an angle measured counterclockwise from said absorber
rₒ is determined by the requirement to connect said bottom reflector first and second wall portions
and further wherein said bottom reflector second wall portion is tangent to said semi-parabolic reflector.

7. A solar concentrator as defined in claim 5, wherein a slope βₜ of said bottom reflector second wall portion is defined by the equation
βₜ=45°+(θᵢ−θₒ)/2.

8. A solar concentrator as defined in claim 5, wherein a slope β_{f} of said bottom reflector first portion at the common plane is greater than
β_{f}=45°−θₒ/2
said slope monotonically increasing from said bottom common plane to a slope βₜ of
βₜ=45°+(θᵢ−θₒ)/2
at the intersection with said bottom reflector second portion.

9. A solar concentrator as defined in claim 1, wherein θᵢ>90°−θₒ where
θᵢ is the rotational angle of said semi-parabolic reflectors
θₒ is the critical angle of said absorber
and further wherein said bottom reflector comprises a first portion extending from said common plane, said first portion having an arcuate configuration and a second portion extending from said first portion to each semi-parabolic apex, said second portion having a concave configuration.

10. A solar concentrator as defined in claim 9, wherein the configuration of said bottom reflector first portion is defined by the equation
r(φ)=cos⁻² α
where:
α=45°−(θₒ+φ)/2
r is measured in focal length units from said focal point
φ is an angle measured counterclockwise from said absorber
said first portion extending from said common plane to a tangent point having a slope βₜ according to the equation
βₜ=90°−θₒ.

11. A solar concentrator as defined in claim 10, wherein the configuration of said bottom reflector second portion is a circular arc centered on said focal point.

12. A solar concentrator as defined in claim 9, wherein a slope β_{f} of said bottom reflector first portion at the common plane is greater than
β_{f}=45°−θₒ/2
said slope monotonically increasing from said bottom common plane to a slope βₜ of
βₜ=45°+(θᵢ−θₒ)/2
at the intersection with said bottom reflector second portion.

13. A solar concentrator as defined in claim 12, wherein the configuration of said bottom reflector second portion is a circular arc centered on said focal point.

14. A solar concentrator as defined in claim 1, wherein said semi-parabolic reflectors have a height relative to a line normal to said common plane and passing through said focal point sufficient to intercept rays of sunlight directed against said semi-parabolic reflectors at an angle less than said rotational angle which produce reflected rays at an angle less than said critical angle of said absorber.

15. A solar concentrator as defined in claim 4, wherein the height A of said reflectors is defined by the equation
A=2 sin θₒ/[1−sin(θₒ−θᵢ)]
where
A is measured in focal length units
θₒ is the absorber critical angle
θᵢ is the angle of semi-parabola reflector rotation.
